(19) United States
(12) Patent Application Publication
(10) Pub. No.: US 2024/0341041 A1
(43) Pub. Date: Oct. 10, 2024

(54) ELECTRONIC SYSTEM ASSEMBLY

(71) Applicant: Epirus, Inc., Torrance, CA (US)

(72) Inventors: Meletios Mastrodemos, Redondo Beach, CA (US); Velimir Nedic, Los Angeles, CA (US); Ryan Frandsen, Broomfield, CO (US); Josh Lehtonen, Los Angeles, CA (US); Jonathan Loughran, Torrance, CA (US)

(21) Appl. No.: 18/624,749

(22) Filed: Apr. 2, 2024

Related U.S. Application Data
(60) Provisional application No. 63/494,099, filed on Apr. 4, 2023.

(51) Int. Cl. H05K 3/36; H05K 1/18

(52) U.S. Cl. CPC H05K 3/36; H05K 1/181; H05K 2201/10098; H05K 2203/0415

(57) ABSTRACT

An electronic system assembly can include a plurality of first circuit boards including a plurality of electronic components provided on first surfaces of the plurality of first circuit boards, a second circuit board including a set of first connectors on a second surface, and a third circuit board including a set of second connectors on a third surface. The first surfaces, a fourth surface of the second circuit board opposite to the second surface, and a fifth surface of the third circuit board opposite to the third surface can define a cavity containing the plurality of electronic components. The set of first connectors and the set of second connectors can be electrically coupled to the plurality of electronic components.

### CROSS-REFERENCE TO RELATED APPLICATIONS

This application claims priority to U.S. Provisional application 63/494,099, filed Apr. 4, 2023, titled “Electronic System Assembly,” which is incorporated by reference in its entirety.

### TECHNICAL FIELD

The present disclosure relates to electronic systems and, more particularly, to assemblies of electronic systems that include a plurality of subsystems.

### SUMMARY

The present disclosure includes an electronic system assembly configured to physically integrate with a second electronic system. The electronic system assembly is configured to receive inputs from the second electronic system, process or convert the inputs, and provide one or more outputs to the second electronic system or to a third system.

The electronic system assembly includes a plurality of first circuit boards including a plurality of electronic components provided on first surfaces of the plurality of first circuit boards; a second circuit board including a set of first connectors on a second surface; and a third circuit board including a set of second connectors on a third surface. When the electronic system assembly is assembled, the first surfaces, a fourth surface of the second circuit board opposite to the second surface, and a fifth surface of the third circuit board opposite to the third surface define a cavity containing the plurality of electronic components within the electronic system assembly, and the set of first connectors and the set of second connectors are electrically coupled to the plurality of electronic components.

In some embodiments, the electronic system assembly includes a first set of the plurality of electronic components on a first board of the plurality of first circuit boards constituting a first electronic subsystem, a second set of the plurality of electronic components on a second board of the plurality of first circuit boards constituting a second electronic subsystem, a third set of the plurality of electronic components on a third board of the plurality of first circuit boards constituting a third electronic subsystem, and a fourth set of the plurality of electronic components on a fourth board of the plurality of first circuit boards constituting a fourth electronic subsystem.

In some embodiments, the electronic system assembly includes the first electronic subsystem, the second electronic subsystem, the third electronic subsystem, and the fourth electronic subsystem are power converters. In some embodiments, the first electronic subsystem and the second electronic subsystem have a common input node and different output nodes. In some embodiments, the first electronic subsystem and the second electronic subsystem are connected in parallel with each other. In some embodiments, an output of the first electronic subsystem is coupled to an input of the second electronic subsystem. In some embodiments, the first electronic subsystem, the second electronic subsystem, the third electronic subsystem, and the fourth electronic subsystem are interconnected as a multi-stage system having an output stage and a plurality of input stages. In some embodiments, the first electronic subsystem, the second electronic subsystem, the third electronic subsystem, and the fourth electronic subsystem are DC-DC power converters configured to provide an output ripple voltage of 40 μV peak-to-peak or less.

In some embodiments, the electronic system assembly includes a support structure having a cuboid shape, wherein, when the electronic system assembly is assembled, the plurality of first circuit boards, the second circuit board, and the third circuit board enclose and are supported by the support structure. In some embodiments, the electronic system assembly includes a support structure having a central column extending between the second circuit board and the third circuit board, and a plurality of pillars extending outwardly from sides of the central column. In some embodiments, the support structure is comprised of a thermally conductive material and, when the electronic system assembly is assembled, the plurality of pillars are each in contact with or adjacent to one or more components of the plurality of electronic components on a set of the plurality of first circuit boards. In some embodiments, the support structure including a plurality of rails located at corners of the central column, wherein, when the electronic system assembly is assembled, each of the plurality of first circuit boards is supported by a pair of rails of the plurality of rails. In some embodiments, each of the plurality of first circuit boards is secured to the support structure via a set of attachment means.

In some embodiments, a set of components of the plurality of electronic components constitute a plurality of electronic subsystems configured to operate independently from each other and to receive a set of inputs via the set of first connectors, the plurality of electronic subsystems configured to provide a plurality of outputs to the set of second connectors based on the set of inputs. In some embodiments, the plurality of electronic subsystems are configured to operate independently based on a plurality of enable signals received via the set of first connectors. In some embodiments, the electronic system assembly includes the plurality of electronic subsystems include a plurality of power converters, the set of inputs include a power input, and the plurality of outputs include a plurality of power outputs.

Embodiments of the present disclosure include a system, comprising a device that includes a plurality of first circuit boards including a plurality of electronic components provided on first surfaces of the plurality of first circuit boards; a second circuit board including a set of first connectors on a second surface; and a third circuit board including a set of second connectors on a third surface. When the electronic system assembly is assembled, the first surfaces, a fourth surface of the second circuit board opposite to the second surface, and a fifth surface of the third circuit board opposite to the third surface define a cavity containing the plurality of electronic components within the electronic system assembly, and the set of first connectors and the set of second connectors are electrically coupled to the plurality of electronic components.

The system comprises a first subsystem including a set of third connectors engaged with the set of first connectors; a power source electrically coupled to the plurality of electronic components via the set of third connectors; a set of fourth connectors engaged with the set of second connectors; and a plurality of electrical loads electrically coupled to the plurality of electronic components via the set of fourth connectors, wherein operation of the plurality of electrical loads is based on operation of the plurality of electronic components.

In some embodiments, the plurality of electronic components constitute a plurality of second subsystems that receive input power from the power source, and the first subsystem includes a controller configured to selectively provide an enable signal to a set of subsystems of the plurality of second subsystems. The set of subsystems generate output as a result of receiving the enable signal. In some embodiments, the plurality of components constitute a plurality of power converters.

In some embodiments, each of the plurality of loads include a plurality of amplifiers selectively powered by the plurality of power converters. In some embodiments, the device includes a support structure having a cuboid shape. When the device is assembled, the plurality of first circuit boards, the second circuit board, and the third circuit board enclose and are supported by the support structure. In some embodiments, the device includes a support structure having a central column extending between the second circuit board and the third circuit board, and a plurality of pillars extending outwardly from sides of the central column.

The support structure is, in some embodiments, comprised of a thermally conductive material and, when the electronic system assembly is assembled, the plurality of pillars are each in contact with or adjacent to one or more components of the plurality of electronic components on a set of the plurality of first circuit boards. In some embodiments, the support structure includes a plurality of rails located at corners of the central column, wherein, when the electronic system assembly is assembled, each of the plurality of first circuit boards is supported by a pair of rails of the plurality of rails.

In some embodiments, wherein a set of components of the plurality of electronic components constitute a plurality of second subsystems configured to operate independently from each other and to receive a set of inputs from the first subsystem via the set of first connectors, the plurality of second subsystems configured to provide a plurality of outputs to the set of second connectors based on the set of inputs.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations.

FIG. 1 illustrates a first perspective view of an electronic system assembly according to one or more embodiments.

FIG. 2 illustrates a perspective view of the electronic system assembly of FIG. 1 according to one or more embodiments.

FIG. 3 illustrates an exploded view of the electronic system assembly of FIG. 1 according to one or more embodiments.

FIG. 4 illustrates a perspective view of a second board of the electronic system assembly of FIG. 1 according to one or more embodiments.

FIG. 5 illustrates a perspective view of a third board of the electronic system assembly of FIG. 1 according to one or more embodiments.

FIG. 6 illustrates a perspective view of a first board of the electronic system assembly of FIG. 1 according to one or more embodiments.

FIG. 7 illustrates a perspective view of a support structure of the electronic system assembly of FIG. 1 according to one or more embodiments.

FIG. 8 illustrates an example block diagram of an electronic system that includes the electronic system assembly of FIG. 1 according to one or more embodiments.

FIG. 9 illustrates an example block diagram of an electronic system that includes the electronic system assembly having a plurality of power converters according to one or more embodiments.

FIG. 10 illustrates an example block diagram of an electronic system that includes the electronic system assembly having a plurality of power converters according to one or more embodiments.

FIG. 11 illustrates an example block diagram of an electronic system that includes the electronic system assembly having a plurality of power converters according to one or more embodiments.

### DETAILED DESCRIPTION

The present disclosure provides examples of an electronic system assembly comprising a plurality of circuit boards arranged in a geometric shape defining a cavity containing a plurality of electronic components distributed over surfaces of a first set of the plurality of circuit boards. The plurality of electronic components is configured as an electronic system comprising a plurality of electronic subsystems distributed over the first set of circuit boards. The plurality of electronic components is electrically coupled to a set of connectors provided on a second set of the circuit boards.

The term “set,” as used herein (e.g., a set of keys), refers to a non-empty collection of members. The phrase “coupled to,” as used herein and unless otherwise indicated by the context of the usage, means that a first circuit element is coupled to a second circuit element, with or without intervening elements therebetween.

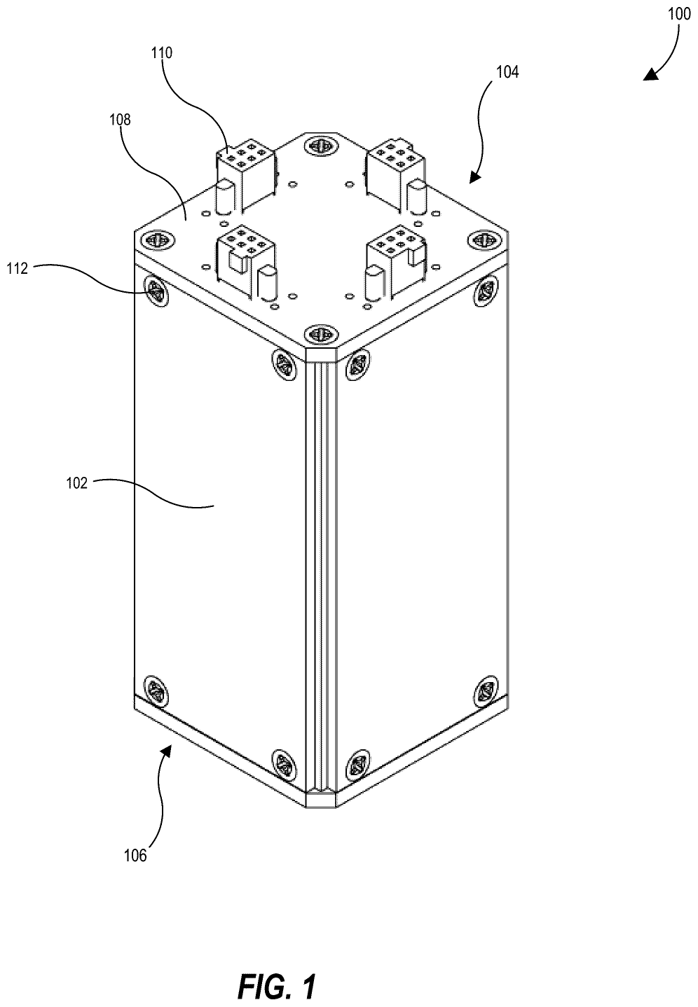

FIG. 1 illustrates a first perspective view of an electronic system assembly 100 according to one or more embodiments. The assembly 100 includes a plurality of sidewalls 102 extending along a first dimension between a first end 104 and a second end 106 opposite to the first end 104. The assembly 100 includes a first surface 108 provided at the first end 104. A set of first connectors 110 are provided on or extend from the first surface 108.

The assembly includes a plurality of attachment means 112 that extend through apertures in the sidewalls 102 and the first surface 108 to retain the assembly 100 together. The attachment means 112 are, in at least some embodiments, fasteners, screws, or bolts that engage with a support structure, as discussed herein. However, other attachment means are considered as being within the scope of the present disclosure. Non-limiting examples of such attachment means include dowels, adhesives, rivets, pins, welds, soldering, and brazing.

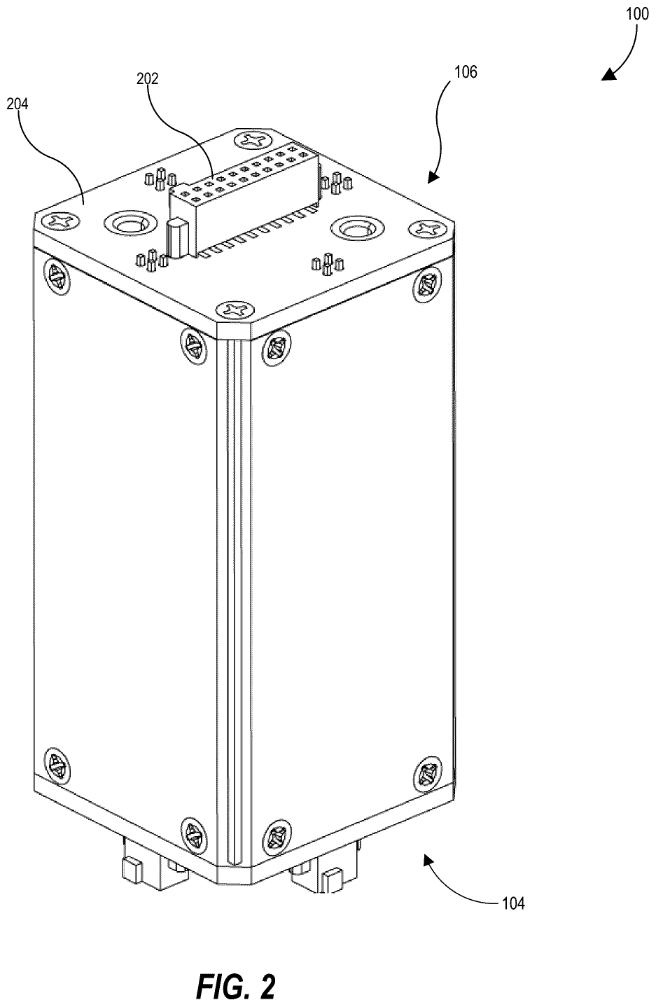

FIG. 2 illustrates a perspective view of an electronic system assembly 100 according to one or more embodiments. The perspective view in FIG. 2 is of the second end 106 of the assembly 100. The second end 106 includes a second connector 202 provided on or extending from a second surface 204 of the assembly 100 opposite to a first surface at the first end 104 thereof.

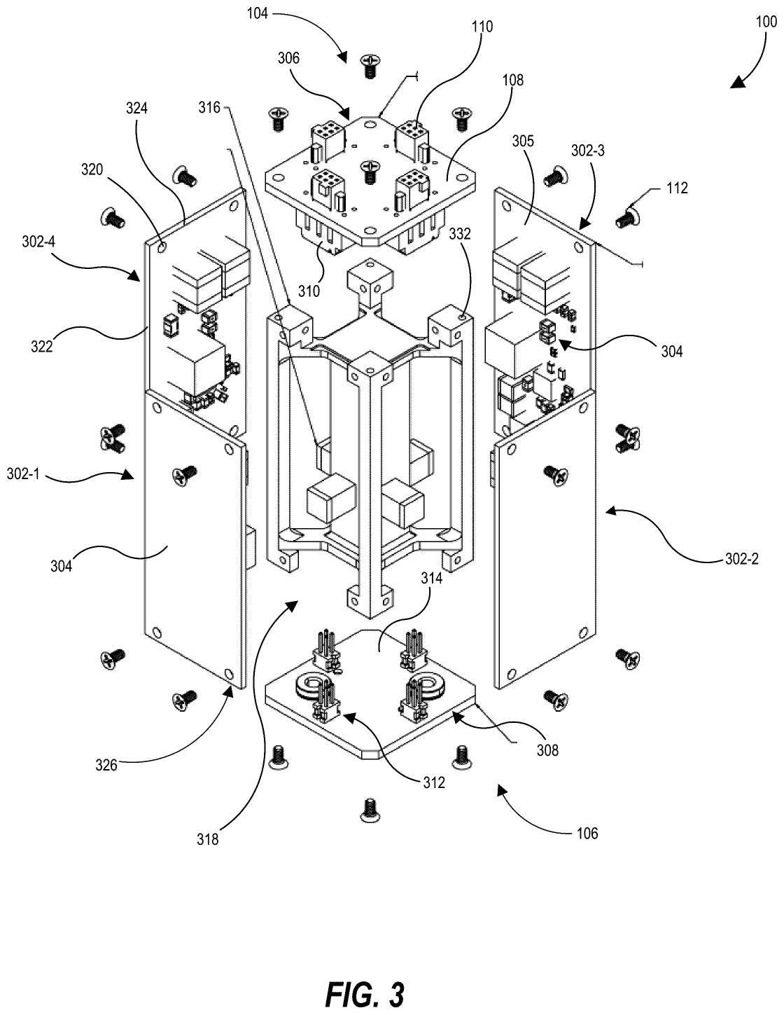

FIG. 3 illustrates an exploded view of the electronic system assembly 100 according to one or more embodiments. The assembly 100 includes a plurality of first boards 302-1, 302-2, 302-3, 302-4 (collectively “first boards 302”) on which the sidewalls 102 are provided. Each of the first boards 302 includes a set of electronic components 304 provided on a surface 305 opposite to the sidewalls 102. The first boards 302 each have substantially similar size and shape to each other.

The assembly 100 also includes a second board 306 provided at the first end 104 of the assembly 100 and includes a third board 308 provided at the second end 106 of the assembly 100 opposite to the first end 104. The second board 306 has a set of third connectors 310 provided on or projecting from a surface opposite to the first surface 108 thereof. Each of the set of third connectors 310 are electrically coupled to a corresponding connector of a set of first connectors 110 via one or more conductors extending through the thickness of the second board 306. The third board 308 has a set of fourth connectors 312 provided on or projecting from a surface 314 of the third board 308 opposing the second board 306.

The assembly 100, in some embodiments, includes a support structure 316. When the assembly 100 is assembled, the support structure 316 is located in a cavity 318 defined by the first boards 302, the second board 306, and the third board 308. In some embodiments, the support structure 316 includes a plurality of apertures 320 sized and shaped to receive the attachment means 112 discussed with respect to FIG. 1 and elsewhere herein. When the assembly 100 is assembled, the attachment means 112 extend through apertures 320 in the first boards 302, the second board 306, or the third board 308, and engage with the apertures 320, thereby securing the assembly 100 together.

When the electronic system assembly 100 is assembled, the first boards 302, the second board 306, and the third board 308 constitute a cuboid shape having six sides. In some embodiments, the electronic system assembly 100 has an elongated cuboid shape in which side edges 322 of the first boards 302 are longer than edges 324 of the first boards 302 at the first end 104 and/or edges 326 of the first boards 302 at the second end 106. In some embodiments, the electronic system assembly 100 may have a cuboid shape in which the side edges 322 of the first boards 302 are approximately equal to the edges 324 of the first boards 302 at the first end 104 and the edges 326 of the first boards 302 at the second end 106. Those of ordinary skill in the art will understand that cuboid geometries other than symmetrical cuboid shapes are within the scope of the present disclosure.

When the electronic system assembly is assembled, the third connectors 310 interface with contacts, traces, or pins of the first boards 302 at or near the edges 324. The interface of the third connectors 310 with the contacts, traces, or pins of the first boards 302 electrically couples the first connectors 110 with the electronic components 304. Also, when the assembly 100 is assembled, the fourth connectors 312 interface with contacts, traces, or pins of the first boards 302 at or near the edges 326. The interface of the fourth connectors 312 with the contacts, traces, or pins of the first boards 302 electrically couples the second connector 202 (see FIG. 2; see also FIG. 5 infra) with the electronic components 304.

When the electronic system 100 is assembled, the plurality of electronic components 304 are contained within the cavity 318. As a result, if any of the electronic components 304 become dislodged due to shock (e.g., sudden deceleration) or vibrational load, the dislodged components remain within the cavity 318 and therefore will not damage any equipment surrounding the electronic system assembly 100.

In some embodiments, one or more conductors are exposed on the side edges 322 and/or surfaces 308 of the first boards 302. The exposed conductor may be coupled to an electrical plane within the first boards 302. When the electronic system assembly 100 is assembled, the exposed conductor(s) may contact the support structure 316, thereby commonly coupling electrical planes in the first boards 302 together. By way of non-limiting example, the exposed conductors may be part of or electrically coupled to a ground plane of the first boards 302. When the electronic system assembly 100 is assembled in such a configuration, the ground planes of the first boards 302 are coupled together via the support structure 316 to provide a common ground.

Features of the electronic system assembly 100 may vary in different embodiments. A shape of the second board 306 and the third board 308 corresponds to a number of the first boards 302. The second board 306 and the third board 308 have a rectangular shape corresponding to the four first boards 302 illustrates and described in FIG. 3. As another non-limiting example, for an electronic system assembly 100 having six of the first boards 302, the second board 306 and the third board 308 would have a hexagonal shape. Those skilled in the art will appreciate that the electronic system assembly 100 may have a different number of first boards 302 depending, e.g., on a number of outputs desired.

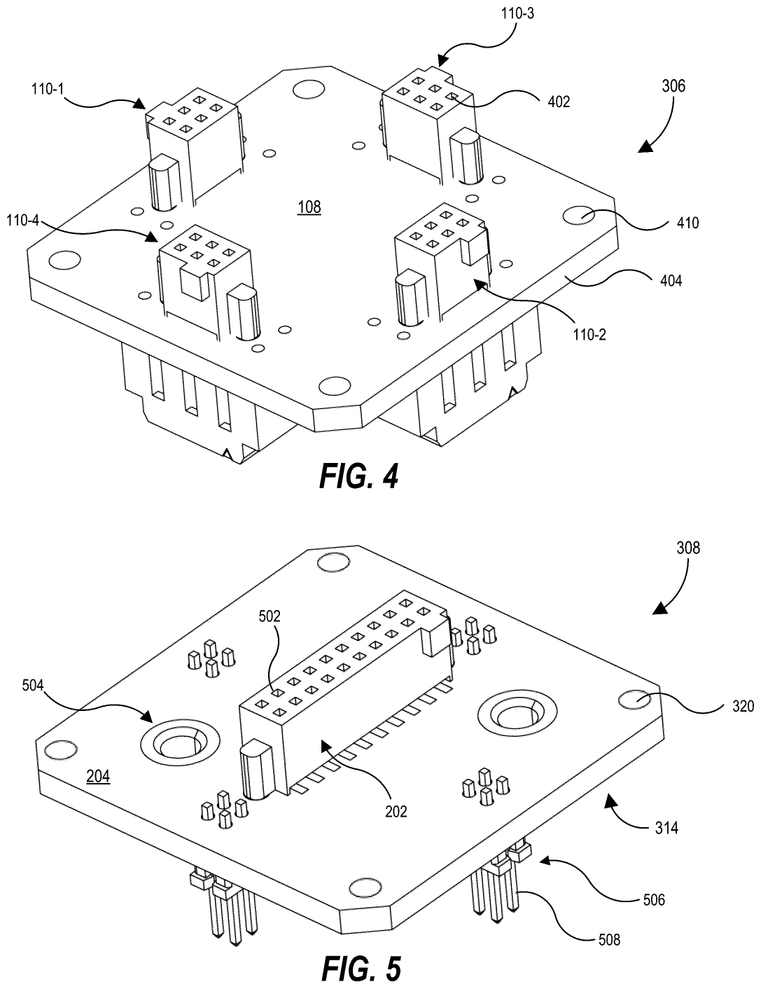

FIG. 4 illustrates a perspective view of the second board 306 of an electronic system assembly according to one or more embodiments. The plurality of first connectors 110-1, 110-2, 110-3, 110-4 (collectively “first connectors 110”) are provided on or project from the first surface 108 of the second board 306. Each of the first connectors 110 includes a plurality of receptacles 402 for receiving a pin or conductor of another apparatus or system with which the electronic system assembly 100 is configured to integrate.

A first pair of the first connectors 110 (e.g., first connectors 110-1 and 110-2) have a first orientation and a second pair of the first connectors (e.g., first connectors 110-3 and 110-4) have a second orientation different than the first orientation. The first and second orientations may correspond with an adjacent edge 404 of the second board 306. In some embodiments, the second board 306 may have only a single connector 110 provided on or protruding from the first surface 108. In some embodiments, the second board 306 may include a different number of the first connectors 110-for example, the second board 306 may have two first connectors 110 instead of the four first connectors 110 shown. The second board 306 includes a plurality of the apertures 320 extending entirely through a thickness of the second board 306.

FIG. 5 illustrates a perspective view of the third board 308 of the electronic system assembly 100 according to one or more embodiments. As discussed with respect to FIG. 2, the second connector 202 is provided on or projects from the surface 204 of the third board 308. The second connector 202 includes a plurality of receptacles 502 for receiving a pin or conductor of another apparatus or system with which the electronic system assembly is configured to integrate.

The third board 308 includes a set of the apertures 320 extending through a thickness thereof. The apertures 320 are each sized and shaped to engage with a corresponding attachment means of the apparatus or system to which the electronic system assembly is configured to integrate. For instance, the apertures 320 may have threading for engaging with corresponding threading of a screw or bolt. In some embodiments, the third board 306 may include a mechanism other than the apertures 320 for attaching the assembly 100 to another apparatus or system.

The third board 308 also includes a set of mounting receptacles 504 extending into or through a thickness of the third board 308. The mounting receptacles 504 may be threaded or otherwise adapted to engage with a corresponding fastener (e.g., bolt, screw, pin) of a device or system with which the electronic system assembly described herein is configured to operate. In some embodiments, the mounting receptacles 504 may instead be a male attachment means projecting from the first surface 204 and adapted to engage with a corresponding female attachment means of a device or system with which the electronic system assembly described herein is configured to operate.

The third board 308 further includes a plurality of conductor sets 506 each comprising a plurality of conductors 508. The conductors 508 include a first portion exposed on or extending from the surface 314 of the third board 308 opposite to the first surface 204. In some embodiments, each of the conductors 508 include a second portion exposed on or extending from the first surface 204 and extend entirely through a thickness of the third board 308 to the second surface 314. Each of the conductors 508 is electrically coupled to one or more conductors in the receptacles 502, e.g., via one or more conductive layers in the third board 308.

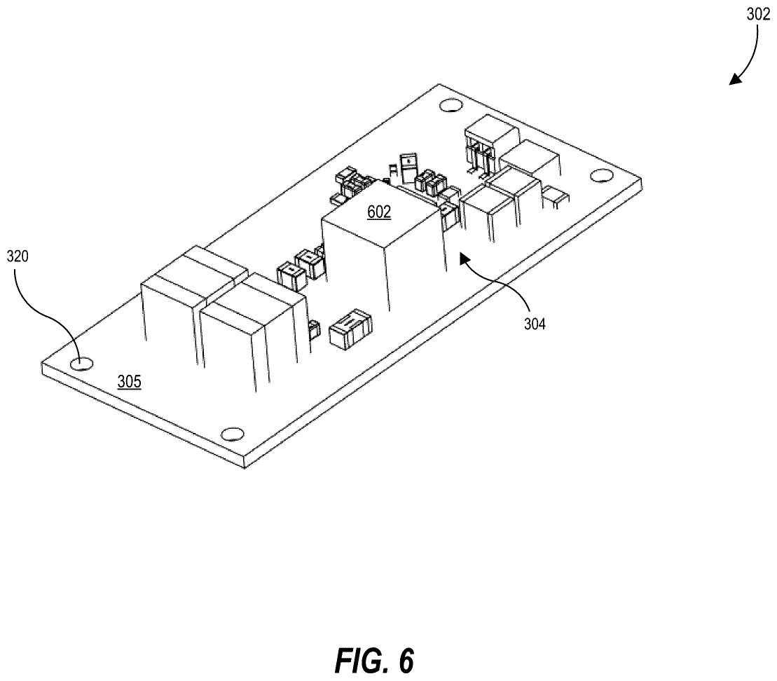

FIG. 6 shows a perspective view of one of the first boards 302 of the electronic system assembly 100 according to one or more embodiments. The first boards 302 each include the surface 305 on which the set of electronic components 304 are disposed. The set of electronic components 304 may include one or more electronic devices 602 that are configured to perform a set of operations. For instance, the one or more electronic devices 602 may include a processor, an integrated circuit, an Application Specific Integrated Circuit, a system-on-chip, or a Field Programmable Gate Array, by way of non-limiting example. As a specific non-limiting example, the electronic device 604 may include a power converter configured to convert input power into another type or level of power. In some embodiments, the first boards 302 include a plurality of the apertures 320 extending through the first board 302 in a thickness direction thereof.

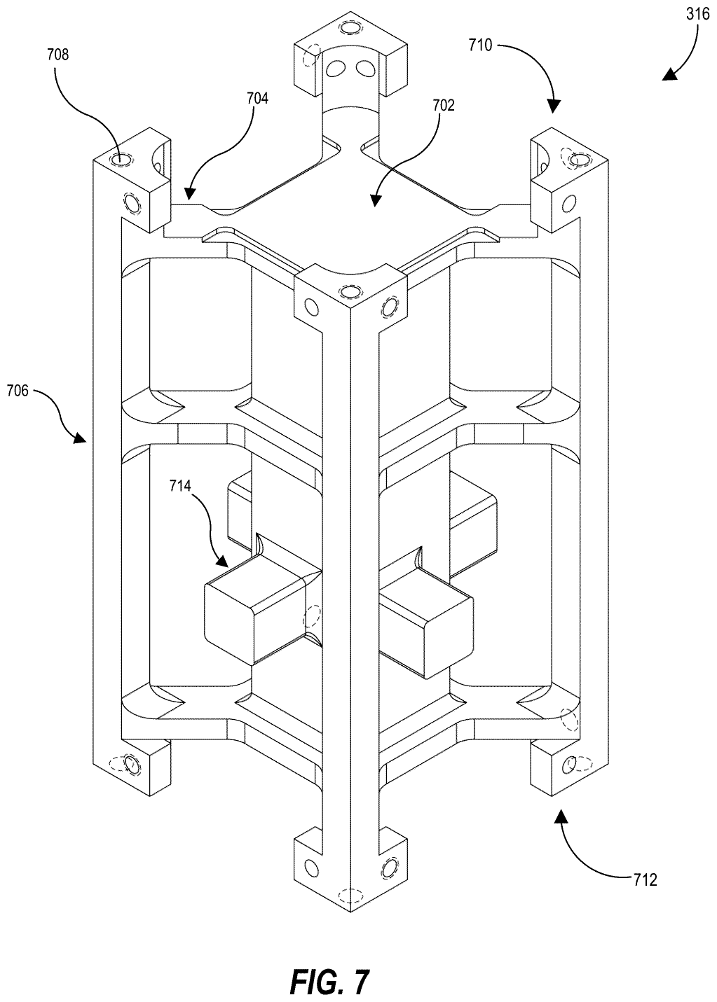

FIG. 7 illustrates a perspective view of an example support structure 316 of an electronic system assembly according to one or more embodiments. In some embodiments, the support structure 316 has a cuboid shape corresponding to shapes of the first boards 302, the second board 306, and the third board 308. The support structure 316 includes a central column 702 extending along a first dimension (e.g., a vertical dimension), a plurality of arms 704 extending outwardly from the central column 702, and a plurality of rails 706 provided at distal ends of the arms 704. When the electronic system assembly is assembled, each of the plurality of first boards 302 (see FIG. 3) is supported by a pair of rails of the plurality of rails 706. In some embodiments, a single rail of the plurality of rails 706 supports two of the first boards 302.

In some embodiments, each of the rails 706 includes a plurality of apertures 708 sized and shaped to receive the attachment means 112, as described with respect to FIG. 1 and elsewhere herein. Each of the rails 706 includes a first set of the apertures 708 located at a first end 710 and a second set of the apertures 708 located at a second end 712 opposite to the first end 710. A first set of the apertures 708 are sized and located to correspond with the apertures 320 in the first boards 302.

In some embodiments, the support structure 316 is a monolithically formed structure. In some embodiments, the central column 702 is composed of a thermally conductive material, such as copper, aluminum, or graphite. In some embodiments, the support structure 316 may be generated using a three-dimensional printer. In some embodiments, the support structure includes a plurality of pillars 714 projecting outwardly from the central column 702. Each of the pillars 714 is located between adjacent rails of the plurality of rails 706 on each side of the central column 702. The pillars 714 are each sized and shaped to be adjacent to or contact with one or more of the electronic components 304 on each of the first boards 302.

When the electronic system assembly 100 is assembled and is in operation, one or more of the pillars 314 absorb heat from one or more of the electronic components 304. The heat is conducted through the central column 702 to effectuate a more even thermal distribution on or from the electronic system assembly. When the electronic system assembly is assembled, the support structure 316 also provides structural rigidity and support for the first boards 302, the second board 306, and the third board 308. As discussed herein, When the electronic system assembly is assembled, the support structure 316 may commonly couple one or more planes of the first boards 302.

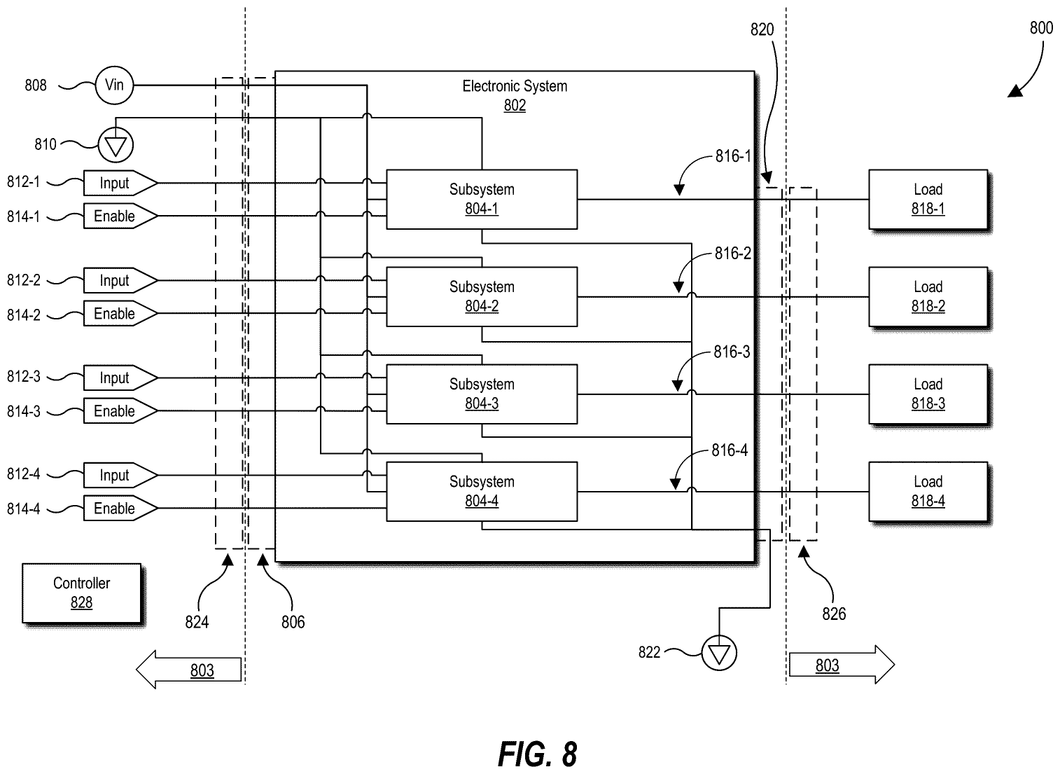

FIG. 8 shows an example block diagram 800 of an electronic system 802 included in an electronic system assembly according to one or more embodiments. The electronic system 802 includes a plurality of electronic subsystems 804-1, 804-2, 804-3, and 804-4 (collectively “subsystems 804”). Each of the subsystems 804 corresponds a set of electronic components 304 on one of the four first boards 302 comprising an electronic system assembly described herein. As a more particular yet non-limiting example with reference to FIG. 3, the subsystem 804-1 may correspond to a set of electronic components provided on the first board 302-1, the subsystem 804-2 may correspond to a set of electronic components provided on the first board 302-2, the subsystem 804-3 may correspond to a set of electronic components provided on the first board 302-3, and the subsystem 804-4 may correspond to a set of electronic components provided on the first board 302-4. The subsystems 804 each provide a different output and are connected in parallel with each other.

The electronic system 802 is configured to connect to a system 803 via a first connector 806. The electronic system 802 is configured to receive a plurality of inputs via the first connector 806, which corresponds, e.g., to the first connectors 110 (see FIG. 4) or the second connector 202 (see FIG. 5). The plurality of inputs are provided to the subsystems 804. The plurality of inputs may include a voltage input 808; ground 810; a plurality of inputs 812-1, 812-2, 812-3, 812-4 (collectively “inputs 812”); and a plurality of enable signals 814-1, 814-2, 814-3, 814-4 (collectively “enable signals 814”), by way of non-limiting example. The enable signals 814 may each enable operation of a respective subsystem of the subsystems 804. The system 803 may include a controller 828 including a processor and memory, the controller 828 configured to selectively provide one or more of the enable signals 814 to individual subsystems 804 based, e.g., on a user input or detection of a defined condition in the system 803. The controller 828 may also selectively activate and/or deactivate the power input 808 based, e.g., on a user input or detection of a defined condition in the system 803.

Each of the subsystems 804-1, 804-2, 804-3, 804-4 is, in some embodiments, respectively configured to generate outputs 816-1, 816-2, 816-3, 816-4 (collectively “outputs 816”) based on a corresponding input of the inputs 812. The outputs 816-1, 816-2, 816-3, 816-4 are respectively provided to loads 818-1, 818-2, 818-3, 818-4 via a second connector 820. The second connector corresponds to one of the first connectors 110 (see FIG. 4) or the second connector 202 (see FIG. 5). In some embodiments, the outputs 816 are referenced with respect to a ground 822 via the second connector 820.

In some embodiments, a characteristic (e.g., voltage level, current level, frequency) of the inputs 812 may individually control an operating mode of corresponding subsystems 804. For instance, the inputs 812-1 and 812-2 may have a first voltage level causing the subsystems 804-1 and 804-2 to operate in a pulsed output mode whereas the inputs 812-3 and 812-4 may have a second voltage level causing the subsystems 804-3 and 804-3 to operate in a continuous output mode. In some embodiments, the inputs 812-1, 812-2, 812-3, 812-4 may be feedback signals from or based on the outputs 816-1, 816-2, 816-3, 816-4. In some embodiments, each of the inputs 812 may include a plurality of inputs that control operation or modes of the subsystems 804.

The system 803 includes the loads 818, one or both of the grounds 810 and 822, the power input 808. The system 803 is also configured to provide the enable signals 814. In some embodiments, the system 803 includes features for providing feedback of the outputs 816 back as the inputs 812. The system 803 includes a connector 824 configured to engage with the first connector 806 to provide at least some of the power input 808, the ground 810, the inputs 812, and the enable signals 814. The system 803 also includes a connector 826 configured to engage with the second connector 820 to provide the outputs 816 to the loads 818. In some embodiments, the connector 824 and/or the connector 826 include a plurality of connectors. For instance, the connector 826 may include a plurality of connectors to engage with the first connectors 110 described and shown with respect to FIG. 4. In some embodiments, one or more of the loads 818 may be part of a system other than the system 803.

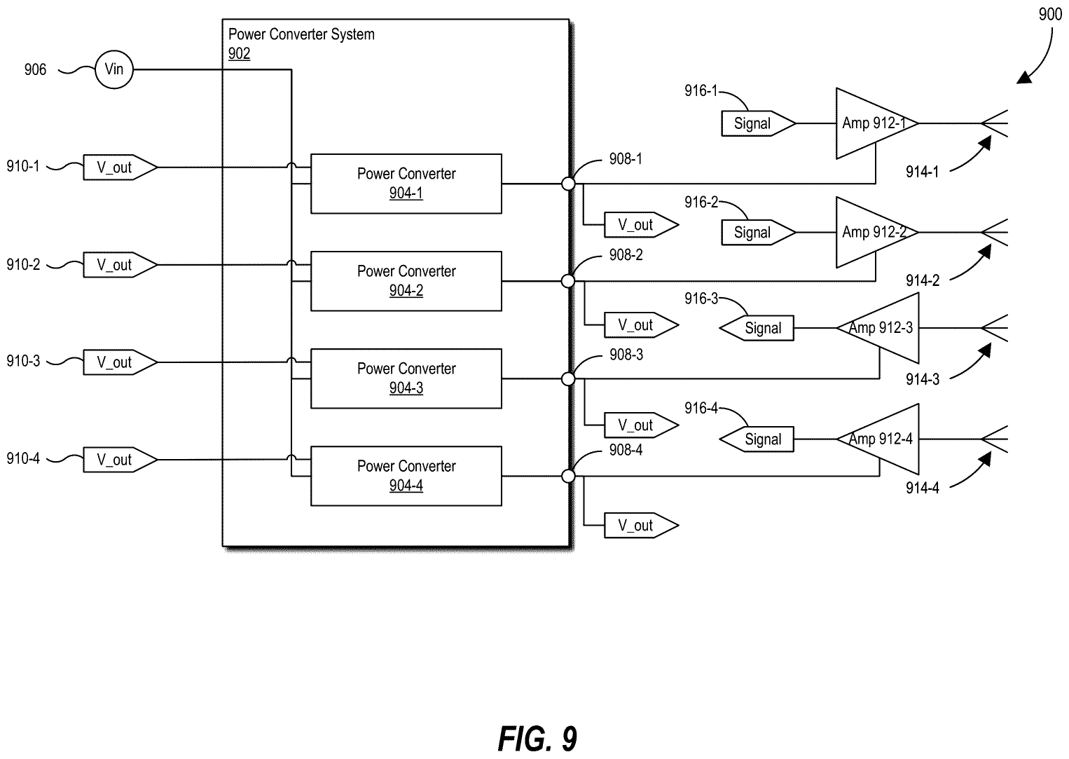

FIG. 9 shows an example block diagram 900 of a power converter system 902 included in an electronic system assembly according to one or more embodiments. Various features of the block diagram 900 are substantially similar to the block diagram 800 so further illustration and description thereof is omitted. The power converter system 902 includes a plurality of power converters 904-1, 904-2, 904-3, 904-4 (collectively “power converters 904”) that, in operation, convert input power 906, such as an input voltage, to output powers 908-1, 908-2, 908-3, 908-4 (e.g., output voltage) having one or more characteristics that are different from one or more characteristics of the input power 906.

Non-limiting examples of the power converters 904 include DC-to-DC converters, AC-to-AC converters, AC-to-DC converters, and power inverters. Specific non-limiting examples of such converters include buck converters, boost converters, buck-boost converters, boost-buck converters, flyback converters, Ćuk converters, SEPIC converters, Zeta converters, voltage-to-frequency converters, frequency-to-voltage converters, cycloconverters, matrix converters, and source inverters. The power converters 904 may include other signal conditioning features such as filters (e.g., low-pass filters, high-pass filter, band-pass filters, band-stop filters), input or output coupling, surge protection, isolation, and linearization, also by way of non-limiting example. In some embodiments, the power converters 904 may have an ultralow noise level on the outputs 908. For instance, the power converters 904 may have an output noise of 4 nV/√Hz over a range of 10 kHz to 4 MHz or higher switching frequencies. The power converters may have an output ripple voltage of 40 μV pk-pk or less.

In some embodiments, the power outputs 908-1, 908-2, 908-3, 908-4 may respectively be fed back as inputs 910-1, 910-2, 910-3, 910-4 (collectively “inputs 910”) to the power converters 904. As a specific non-limiting example of an application of the power converter system 902, the power outputs 908 may be provided to power a plurality of amplifiers 912-1, 912-2, 912-3, 912-4 (collectively “amps 912”). The power converters 904 may include control circuitry that adjusts operational characteristics based on the inputs 910. In some embodiments, the outputs 908 are fed back internally through the power converter system 902 back to the inputs 910. In some embodiments, the outputs 908 are fed back externally to the inputs 910.

As a further specific non-limiting example, the power converter system 902 may be implemented in a radio frequency (RF) transmit and/or receive system. The block diagram 900, for instance, includes a plurality of antennae 914-1, 914-2, 914-3, 914-4 (collectively “antennae 914”) respectively electrically coupled to the amps 912-1, 912-2, 912-3, 912-4. Inputs/outputs of the amps 912 may be coupled to transmit RF signals via one or more of the antennae 914 or coupled to receive RF signals via one or more of the antennae 914. The power converters 904 may be individually and selectively activated/deactivated based on the enable signals 814 described with respect to FIG. 8. The power converters 904 may be enabled immediately before (e.g., <100 ns) an RF signal is to be received or transmitted.

The amps 912-1 and 912-2 may be coupled to receive RF signals 916-1 and 916-2 (e.g., from a communication system coupled to an input of the amps 912-1 and 912-2 via cable or wire), amplify the RF signals 916-1 and 916-2, and transmit the amplified signals via the antennae 914-1 and 914-2. The amps 912-3 and 912-4 may be coupled to receive RF signals via the antennae 914-3 and 914-4, amplify the RF signals, and send amplified RF signals 916-3 and 916-4 (e.g., from outputs of the amps 912-3 and 916-4 to a communication system via cable or wire). In some embodiments, the amps 912 may be coupled to transmit RF signals via the antennae 914. In some embodiments, the amps 912 may be coupled to receive RF signals via the antennae 914. In some embodiments, each of the power converters 904 includes an input filter and/or an output filter to filter out undesirable electromagnetic noise or interference.

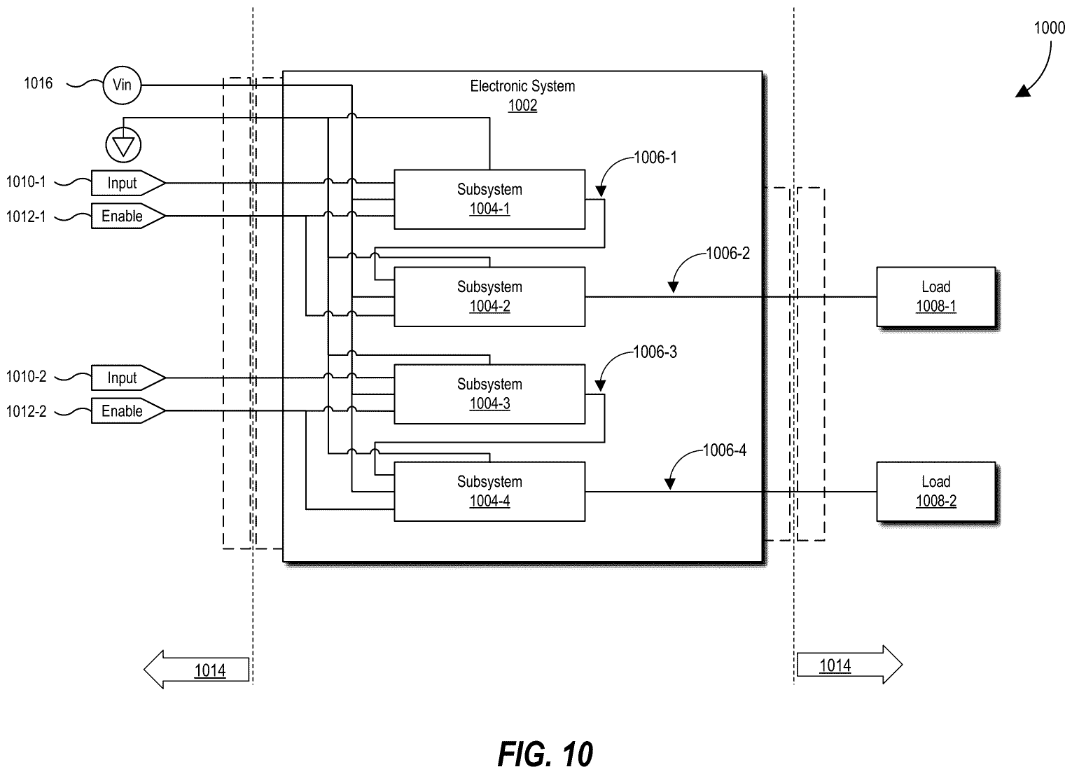

FIG. 10 shows an example block diagram 1000 of an electronic system 1002 included in an electronic system assembly according to one or more embodiments. Various features of the block diagram 1000 are substantially similar to features depicted in and described with respect to the block diagram 800, so further description and illustration thereof is omitted. The electronic system 1002 includes a plurality of electronic subsystems 1004-1, 1004-2, 1004-3, and 1004-4 (collectively “subsystems 1004”). Each of the subsystems 1004 corresponds a set of electronic components 304 on one of the four first boards 302 comprising an electronic system assembly described herein.

In the block diagram 1000, the electronic system 1002 has two or more subsystems 1004 connected in series with each other. For instance, The subsystems 1004-1 and 1004-2 are connected in series and the subsystems 1004-3 and 1004-4 are connected in series. More particularly, an output 1006-1 of the subsystem 1004-1 is connected as an input to the subsystem 1004-2. An output 1006-2 of the subsystem 1004-2 is connected to a load 1008-1. An output 1006-3 of the subsystem 1006-3 is connected as an input to the subsystem 1004-4. An output 1006-4 of the subsystem 1004-4 is connected to a load 1008-2.

An input 1010-1 is connected to an input terminal of the subsystem 1004-1 and an input 1010-2 is connected to an input terminal of the subsystem 1004-2. In some embodiments, an enable signal 1012-1 is connected to enable terminals of the subsystems 1004-1 and 1004-2. An enable signal 1012-2 is connected to enable terminals of the subsystems 1004-3 and 1004-4. The output 1006-1 is generated based at least in part on the input 1010-1. The subsystem 1004-2 generates the output 1006-2 based at least in part on the output 1006-1. The output 1006-3 is generated based at least in part on the input 1010-2. The subsystem 1004-4 generates the output 1006-4 based at least in part on the output 1006-3. One or more of the subsystems 1004 may receive additional inputs (e.g., from a system 1014 external to the electronic system 1002) adjusting operational parameters thereof.

The subsystems 1004-1 and 1004-3 may have different functionality than the subsystems 1004-2 and 1004-4. For instance, the electronic system 1002 may be configured to convert a DC voltage input 1016 to two AC voltage outputs 1006-2 and 1006-4. The subsystems 1004-1 and 1004-3 may be DC-DC converters comprising, e.g., a boost converter, an inverter circuit, and a rectifier circuit that collectively convert the DC voltage input 1016 having a first voltage level to DC voltage outputs 1006-1 and 1006-3 having a second voltage level. The subsystems 1004-2 and 1004-4 may be DC-AC converters comprising an inverter circuit and an output filter that are collectively configured to convert the DC voltage outputs 1006-1 and 1006-3 to AC voltage outputs 1006-2 and 1006-4, respectively. In some embodiments, the subsystem 1004-4 may include a phase shifter configured to shift a phase of the AC voltage output 1006-4 by a defined amount relative to the AC voltage output 1006-2.

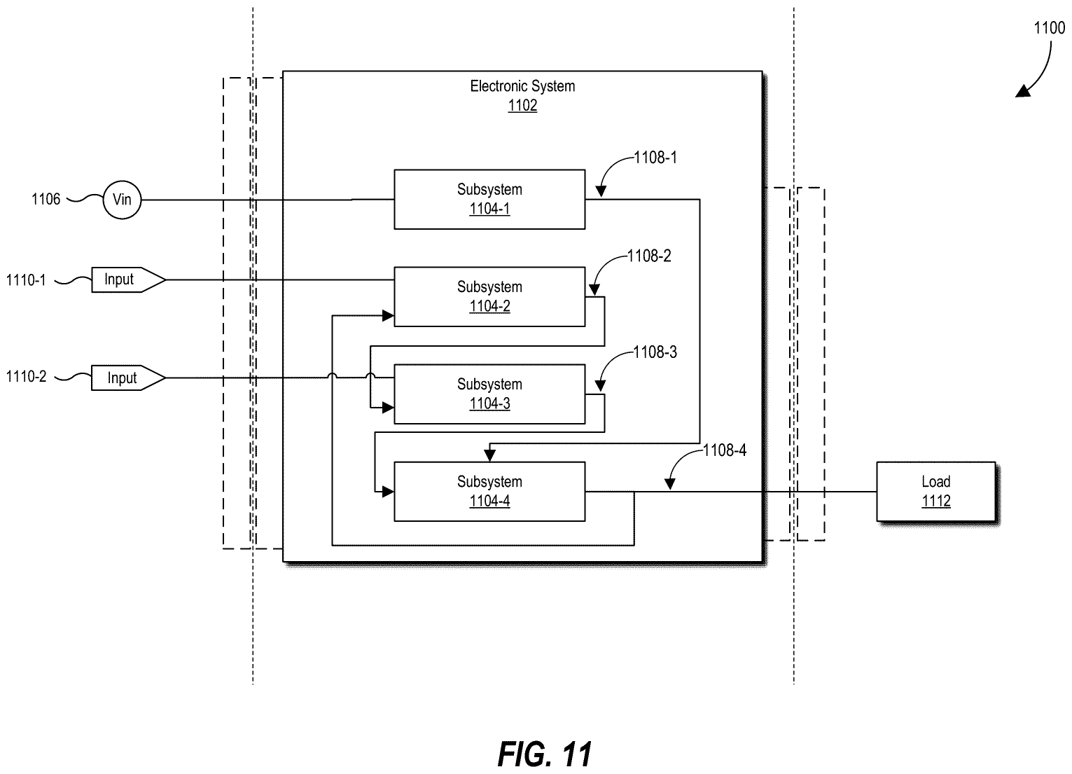

In some embodiments, the electronic system may be a multi-stage device, such as a variable AC-DC power supply. FIG. 11 shows a block diagram 1100 that includes an electronic system 1102 comprising subsystems 1104-1, 1104-2, 1104-3, and 1104-4. The subsystem 1104-1 includes a transformer having an N:1 or 1:N winding ratio, a bridge rectifier, and filtering components (e.g., capacitors). An input of the subsystem 1104-1 may be connected to an AC input voltage 1106, such as a 240V 60 Hz AC source. The subsystem 1104-1 may convert the AC input voltage to a DC voltage 1108-1 based on the transformer winding ratio.

The subsystem 1104-4 may be a Buck converter circuit configured to convert the DC voltage 1108-1 to a DC output voltage 1108-4 having a different voltage level than the DC voltage 1108-1. The subsystem 1104-2 may include an output scaling stage (e.g., including a voltage divider) and a differential amplifier stage. The subsystem 1104-2 is connected to receive an input 1110-1, which may be a selectively adjustable reference signal or a selectively adjustable circuit component, such as a potentiometer. In some embodiments, the input 1110-1 may be set at a defined voltage value based on values of one or more resistors. The input 1110-1 is connected to a first input terminal of a differential amplifier circuit and the output scaling stage is connected to a second input terminal of the differential amplifier circuit. The differential amplifier circuit generates a DC output 1108-2 having a gain based on a difference between the input 1110-1 and a signal from the output scaling stage.

The subsystem 1104-3 includes a comparator circuit that is coupled to receive an input 1110-2 that is, in some embodiments, a periodic signal, such as a triangle wave. The comparator circuit generates a pulse-width-modulated (PWM) signal 1108-3 based on a comparison between the input 1110-2 and the DC output 1108-2. The PWM signal 1108-3 is coupled to an input of the Buck converter circuit of the subsystem 1104-4. The subsystem 1104-4 generates a DC output voltage 1108-4 based on the PWM signal 1108-3. The DC output voltage 1108-4 is fed back to the output scaling circuit in the subsystem 1104-2 and a pulse width of the PWM signal 1108-3 is adjusted based on the feedback.

The electronic system 1102 may be configured to recharge a load 1112, such as a battery in an electric vehicle. The electronic system 1102 and parameters of inputs thereto may be adjusted to charge batteries, e.g., based on their state of charge or other characteristics particular to the battery, such as a target resting voltage. Those skilled in the art will appreciate that the electronic system 1102 may have a multitude of other configurations to achieve complex functionality in a compact form factor.

### Other Variations

Features, materials, characteristics, or groups described in conjunction with a particular aspect, embodiment, or example are to be understood to be applicable to any other aspect, embodiment or example described herein unless incompatible therewith. All the features disclosed in this specification (including any accompanying claims, abstract and drawings), and/or all the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

While certain embodiments have been described, these embodiments have been presented by way of example only and are not intended to limit the scope of protection. Indeed, the novel methods and systems described herein may be embodied in a variety of other forms. Furthermore, various omissions, substitutions, and changes in the form of the methods and systems described herein may be made. Those skilled in the art will appreciate that in some embodiments, the actual steps taken in the processes disclosed and/or illustrated may differ from those shown in the figures. Depending on the embodiment, certain of the steps described above may be removed, others may be added. For example, the actual steps and/or order of steps taken in the disclosed processes may differ from those described and/or shown in the figure. Depending on the embodiment, certain of the steps described above may be removed, others may be added. For instance, the various components illustrated in the figures and/or described may be implemented as software and/or firmware on a processor, controller, ASIC, FPGA, and/or dedicated hardware. Furthermore, the features and attributes of the specific embodiments disclosed above may be combined in different ways to form additional embodiments, all of which fall within the scope of the present disclosure.

In some cases, there is provided a non-transitory computer readable medium storing instructions, which when executed by at least one computing or processing device, cause performing any of the methods as generally shown or described herein and equivalents thereof.

Any of the memory components described herein can include volatile memory, such random-access memory (RAM), dynamic random-access memory (DRAM), synchronous dynamic random-access memory (SDRAM), double data rate (DDR) memory, static random-access memory (SRAM), other volatile memory, or any combination thereof. Any of the memory components described herein can include non-volatile memory, such as magnetic storage, flash integrated circuits, read only memory (ROM), Chalcogenide random access memory (C-RAM), Phase Change Memory (PC-RAM or PRAM), Programmable Metallization Cell RAM (PMC-RAM or PMCm), Ovonic Unified Memory (OUM), Resistance RAM (RRAM), NAND memory (e.g., single-level cell (SLC) memory, multi-level cell (MLC) memory, or any combination thereof), NOR memory, EEPROM, Ferroelectric Memory (FeRAM), Magnetoresistive RAM (MRAM), other discrete NVM (non-volatile memory) chips, or any combination thereof.

Any user interface screens illustrated and described herein can include additional and/or alternative components. These components can include menus, lists, buttons, text boxes, labels, radio buttons, scroll bars, sliders, checkboxes, combo boxes, status bars, dialog boxes, windows, and the like. User interface screens can include additional and/or alternative information. Components can be arranged, grouped, displayed in any suitable order.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without other input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, or within less than 0.01% of the stated amount.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations.

The foregoing description, for purposes of explanation, used specific nomenclature to provide a thorough understanding of the disclosure. However, it will be apparent to one skilled in the art that specific details are not required in order to practice the disclosed embodiments. Thus, the foregoing descriptions of specific embodiments are presented for purposes of illustration and description. They are not intended to be exhaustive or to limit the disclosure to the precise forms disclosed; obviously, many modifications and variations are possible in view of the above teachings. The embodiments were chosen and described in order to best explain the principles of the disclosure and its practical applications, they thereby enable others skilled in the art to best utilize the disclosure and various embodiments with various modifications as are suited to the particular use contemplated. It is intended that the claims as presented herein or as presented in the future and their equivalents define the scope of the protection.

1. An electronic system assembly, comprising:
a plurality of first circuit boards including a plurality of electronic components provided on first surfaces of the plurality of first circuit boards;
a second circuit board including a set of first connectors on a second surface; and
a third circuit board including a set of second connectors on a third surface,
wherein:
the first surfaces, a fourth surface of the second circuit board opposite to the second surface, and a fifth surface of the third circuit board opposite to the third surface define a cavity containing the plurality of electronic components, and
the set of first connectors and the set of second connectors are electrically coupled to the plurality of electronic components.

2. The electronic system assembly of claim 1, wherein a first set of the plurality of electronic components on a first board of the plurality of first circuit boards constitutes a first electronic subsystem, a second set of the plurality of electronic components on a second board of the plurality of first circuit boards constitutes a second electronic subsystem, a third set of the plurality of electronic components on a third board of the plurality of first circuit boards constitutes a third electronic subsystem, and a fourth set of the plurality of electronic components on a fourth board of the plurality of first circuit boards constitutes a fourth electronic subsystem.

3. The electronic system assembly of claim 2, wherein the first electronic subsystem, the second electronic subsystem, the third electronic subsystem, and the fourth electronic subsystem are power converters.

4. The electronic system assembly of claim 2, wherein the first electronic subsystem and the second electronic subsystem comprise a common input node and different output nodes.

5. The electronic system assembly of claim 2, wherein the first electronic subsystem and the second electronic subsystem are connected in parallel with each other.

6. The electronic system assembly of claim 2, wherein an output of the first electronic subsystem is coupled to an input of the second electronic subsystem.

7. The electronic system assembly of claim 2, wherein the first electronic subsystem, the second electronic subsystem, the third electronic subsystem, and the fourth electronic subsystem are interconnected as a multi-stage system comprising an output stage and a plurality of input stages.

8. The electronic system assembly of claim 2, wherein the first electronic subsystem, the second electronic subsystem, the third electronic subsystem, and the fourth electronic subsystem are DC-DC power converters configured to provide an output ripple voltage of 40 μV peak-to-peak or less.

9. The electronic system assembly of claim 1, further comprising:
a support structure having a cuboid shape, wherein the plurality of first circuit boards, the second circuit board, and the third circuit board enclose and are supported by the support structure.

10. The electronic system assembly of claim 1, further comprising:
a support structure including:
a central column extending between the second circuit board and the third circuit board, and
a plurality of pillars extending outwardly from sides of the central column, wherein the support structure is comprised of a thermally conductive material and the plurality of pillars are each in contact with or adjacent to one or more components of the plurality of electronic components on a set of the plurality of first circuit boards.

11. The electronic system assembly of claim 10, wherein the support structure includes a plurality of rails located at corners of the central column, and wherein each circuit board of the plurality of first circuit boards is supported by a pair of rails of the plurality of rails.

12. The electronic system assembly of claim 11, wherein each circuit board of the plurality of first circuit boards is secured to the support structure via a set of attachment means.

13. The electronic system assembly of claim 1, wherein a set of components of the plurality of electronic components constitute a plurality of electronic subsystems configured to operate independently from each other and to receive a set of inputs via the set of first connectors, the plurality of electronic subsystems configured to provide a plurality of outputs to the set of second connectors based on the set of inputs.

14. The electronic system assembly of claim 13, wherein the plurality of electronic subsystems are configured to operate independently based on a plurality of enable signals received via the set of first connectors.

15. The electronic system assembly of claim 13, wherein the plurality of electronic subsystems include a plurality of power converters, the set of inputs include a power input, and the plurality of outputs include a plurality of power outputs.

16. A system, comprising:
a device including:
a plurality of first circuit boards including a plurality of electronic components provided on first surfaces of the plurality of first circuit boards;
a second circuit board including a set of first connectors on a second surface; and
a third circuit board including a set of second connectors on a third surface,
wherein:
the first surfaces, a fourth surface of the second circuit board opposite to the second surface, and a fifth surface of the third circuit board opposite to the third surface define a cavity containing the plurality of electronic components, and
the set of first connectors and the set of second connectors are electrically coupled to the plurality of electronic components; and
a first subsystem including:
a set of third connectors engaged with the set of first connectors;
a power source electrically coupled to the plurality of electronic components via the set of third connectors;
a set of fourth connectors engaged with the set of second connectors; and
a plurality of electrical loads electrically coupled to the plurality of electronic components via the set of fourth connectors, wherein operation of the plurality of electrical loads is based on operation of the plurality of electronic components.

17. The system of claim 16, the plurality of electronic components constituting a plurality of second subsystems that receive input power from the power source, and
the first subsystem including:
a controller configured to selectively provide an enable signal to a set of subsystems of the plurality of second subsystems, wherein the set of subsystems generate output as a result of receiving the enable signal.

18. The system of claim 16, wherein the plurality of electronic components constitute a plurality of power converters.

19. The system of claim 18, wherein each circuit board of the plurality of electrical loads include a plurality of amplifiers selectively powered by the plurality of power converters.

20. The system of claim 16, the device further including:
a support structure having a cuboid shape, wherein the plurality of first circuit boards, the second circuit board, and the third circuit board enclose and are supported by the support structure.

21. The system of claim 16, the device further including:
a support structure including:
a central column extending between the second circuit board and the third circuit board, and
a plurality of pillars extending outwardly from sides of the central column, wherein the support structure is comprised of a thermally conductive material and the plurality of pillars are each in contact with or adjacent to one or more components of the plurality of electronic components on a set of the plurality of first circuit boards.

22. The system of claim 21, wherein the support structure includes a plurality of rails located at corners of the central column, and wherein each circuit board of the plurality of first circuit boards is supported by a pair of rails of the plurality of rails.

23. The system of claim 16, wherein a set of components of the plurality of electronic components constitute a plurality of second subsystems configured to operate independently from each other and to receive a set of inputs from the first subsystem via the set of first connectors, the plurality of second subsystems configured to provide a plurality of outputs to the set of second connectors based on the set of inputs.
